(19) United States
(12) Patent Application Publication
(10) Pub. No.: US 2023/0249965 A1
(43) Pub. Date: Aug. 10, 2023

(54) HYDRODYNAMIC AND GRAVITY FOCUSING APPARATUS AND METHOD OF FORMING AND SHAPING MICROFLUIDIC DEVICES

(71) Applicant: HUMMINGBIRD NANO, INC., Nicholasville, KY (US)

(72) Inventor: Eleanor Augusta Derbyshire, Lexington, KY (US)

(21) Appl. No.: 17/960,120

(22) Filed: Oct. 4, 2022

Related U.S. Application Data
(63) Continuation-in-part of application No. 17/380,327, filed on Jul. 20, 2021.
(60) Provisional application No. 63/252,139, filed on Oct. 4, 2021.

(51) Int. Cl. B81C 99/00; B29C 48/335; B29C 48/00

(52) U.S. Cl. CPC B81C 99/0015; B29C 48/338; B29C 48/022; B81C 2900/02

(57) ABSTRACT

A curable sheath fluid and a core fluid are simultaneously introduced from a hydrodynamic nozzle to form a co-flowing extrusion, depositing at least a portion of the co-flowing extrusion on a material bed, and causing relative motion between the hydrodynamic nozzle and the material bed to form an extruded shape. The method comprises curing part or all of the external curable fluid. The method may introduce co-flowing extrusion to pressure to remove the internal core fluid from the external curable fluid, and may receive the core fluid into the fluid drain system. The extruded shapes may form a tube or plurality of tubes in a bundle or porous substrate. The ability to form concentric tubes and complex shapes provides a means forming high strength materials controlled release materials, and self-repair materials.

### CROSS-REFERENCE TO RELATED APPLICATIONS

This is a Continuation-In-Part application to U.S. application Ser. No. 17/380,327 filed on Jul. 20, 2021 and claims priority from U.S. Provisional Application Ser. No. 63/252,139 filed on Oct. 4, 2021 both of which are hereby incorporated by reference herein in their entirety.

### STATEMENT REGARDING FEDERALLY SPONSORED RESEARCH

None.

### BACKGROUND

### Field of the Disclosure

The present disclosure relates to three-dimensional fabrication and shaping of microfluidic devices using hydrodynamic focusing.

### Description of the Related Art

Hydrodynamic focusing is a scientific concept for creating a flow of an outer “sheath” fluid surrounding a core fluid within a closed tube or channel.

Hydrodynamic focusing is involved in microfluidic applications such as ultra-fast mixers, micro-reactors, and cytometry as a technique for counting, examining and sorting microscopic particles suspended in a stream of fluid, and microfabrication. Chemical synthesis is faster and small volumes and high area to volume ratios offer an advantage over conventional analysis methods.

Hydrodynamic focusing is described by Navier-Stokes equations for 3-dimensional flow, and various trends and approximations (described below) have been developed to describe the behavior of the fluids. Both the sheath and the core fluid are laminar in flow, and Reynolds numbers between 1-10 are generally preferred to create continuous core flow (Spatiotemporal instability of a confined capillary jet, Herrada M A, Galian-Calvo A M, Guillot P. Phys. Rev. E. 2008; 78:046312). The diameter of the inner fluid is determined by the ratio of viscosities, flow rates, geometry of the surrounding channel prior to ejection from the channel, and the continuous phase capillary number (for the sheath flow with respect to the core fluid). For a given set of fluids, the result is that by adjusting the flow rate, one can adjust the cross-sectional diameter of the core fluid and alter the output.

Hydrodynamic focusing is dominated by three elements: 1) The ratio of the core viscosity to the sheath viscosity; 2) continuous phase capillary number for the core flow, and; 3) the geometry of the structure through which both fluids flow. It is theorized that inertia is an important factor with regards to the transition between jetting, which is continuity of the core diameter, and droplet formation (Spatiotemporal instability of a confined capillary jet, Herrada M A, Gañán-Calvo A M, Guillot P. Phys. Rev. E. 2008; 78:046312 and Stability of a Jet in Confined Pressure-Driven Biphasic Flows at Low Reynolds Numbers, Guillot P, Colin A, Utada A S, Ajdari A. Phys. Rev. Lett. 2007; 99:104502).

The viscosity ratio of μ_{d}/μ_{c} (where μ_{d} is the viscosity of the core fluid and μ_{c} is the viscosity of the sheath fluid) is useful because as this ratio decreases, the dripping regime increases. There is a transitional regime between droplet formation and jetting (continuous core flow) (Nunes J K, Tsai S S, Wan J, Stone H A. Dripping and jetting in microfluidic multiphase flows applied to particle and fiber synthesis. J Phys D Appl Phys. 2013; 46(11):114002. doi:10.1088/0022-3727/46/11/114002).

The continuous phase capillary number is:

$${Ca}_{c} = \frac{{μ}_{c} {U}_{c}}{γ}$$

where μc is the viscosity of the sheath fluid, U_{C} is the velocity of the sheath fluid, and ? is the interfacial energy, There is currently insufficient data to correlate a Ca_{c} number to the transition between droplet formatting and jetting (Nunes J K, Tsai S S, Wan J, Stone H A. Dripping and jetting in microfluidic multiphase flows applied to particle and fiber synthesis. J Phys D Appl Phys. 2013; 46(11):114002, doi:10.1088/0022-3727/46/11/114002). As the Ca_{c} number increases, the core flow moves to jetting. The Ca_{c} can also be increased by lowering the interfacial energy by techniques such as adding surfactants to the fluids, creating partially miscible fluids (Nunes J K, Tsai S S, Wan J, Stone H A, Dripping and jetting in microfluidic multiphase flows applied to particle and fiber synthesis. J Phys D Appl Phys. 2013; 46(11):114002. doi:10.1088/0022-3727/46/11/114002).

For flow within a cylinder, the radius of the core fluid can be estimated as: the radius of the core fluid and R is the channel radius (Jeong W, Kim J, Kim S, Lee S, Mensing C, Beebe D J, Lab Chip. 2004; 4: 576-580),

$${R}_{d} = {R [ 1 - {( \frac{{Q}_{c}}{{Q}_{d} + {Q}_{c}} )}^{1 / 2} ]}^{1 / 2}$$

A the experimental level, a filament was created by using a two-component mixture The sheath fluid contained 3% benzoyl peroxide. The polymerizable resin was polyethylene glycol 400 diacrylate. (Book, 3D Printed Microfluidic Devices, edited by Savas Tasoglu, Albert Folch, MDPI AG, Dec. 21, 2018, pg 19), This approach is not at all similar to the present disclosure, but demonstrates the desire to create three-dimensional shapes by using hydrodynamic methods.

### SUMMARY

The present disclosure provides a method and apparatus for forming extruded shapes having at least a hollow portion using a hydrodynamic nozzle, a curable fluid, and a focusing fluid. The extruded shapes may form a tube or plurality of tubes in a bundle or porous substrate. The ability to form concentric tubes and complex shapes provides a means forming high strength materials controlled release materials, and self-repair materials, etc.

The present invention is an apparatus for forming an extruded shape comprising a hydrodynamic nozzle capable of simultaneous movement in x-, y-, z- or theta-directions for creating a co-flowing coaxial extrusion forming an external curable sheath fluid with an internal core fluid and a curing system such as an ultraviolet (UV) curing system at least partially cures the external curable sheath fluid. A positive or negative pressure system removes the internal core fluid from the external curable sheath fluid. A material bed capable of simultaneous linear movement in the x, y, or z direction receives at least a portion of a co-flowing coaxial extrusion. A control system causes relative movement between the hydrodynamic nozzle and the material bed, and a fluid drain system receives the core fluid. A ferro system capable of changing the position or cross-sectional shape can be used on the co-flowing coaxial extrusion.

The apparatus comprises a hydrodynamic nozzle, a curing system, a material bed, a control system and optionally a pressure system and a fluid drain system. The method comprises simultaneously introducing a curable sheath fluid and a core fluid from the hydrodynamic nozzle to form a concentric extrusion, depositing at least a portion of the concentric extrusion on the material bed, and causing relative motion between the hydrodynamic nozzle and the material bed to form an extruded shape. The method further comprises curing or partially curing part or all of the external curable fluid. The method may optionally may introduce the concentric extrusion to pressure from the pressure system to remove the internal core fluid from the external curable fluid, and may optionally receiving the core fluid into the fluid drain system.

More particularly, the present invention comprises the steps of forming an extruded shape, comprising providing a hydrodynamic nozzle, a curing system, a material bed, a control system, and a gravity fed system. An optional fluid drain system is useful. A curable sheath fluid and a core ferro fluid flow simultaneously from the hydrodynamic nozzle to form a concentric extrusion comprising an external sheath fluid and an internal core fluid. The core fluid is exposes to a magnetic force and at least a portion of the concentric extrusion is deposited on the material bed causing relative motion between the hydrodynamic nozzle and the material bed to form an extruded shape and at least partially curing a portion of the external curable fluid. Introducing the concentric extrusion to pressure from the pressure system removes the internal core fluid from the external curable fluid. The core fluid is optionally received into the fluid drain system. In addition, products produced from the method include extruded shapes forming a tube or plurality of tubes in a bundle or porous substrate. The ability to form concentric tubes and complex shapes provides a means forming high strength materials controlled release materials, and self-repair materials.

Chemicals, light, heat, viscosity, pH, radiation, and exposure to gases such as air can affect curing of some substrates; however, it is advantageous to be able to change the shape of the extruded property by external forces without effecting the chemical structure of the core or sheath materials.

The present invention to use process manipulation to provide a process whereby fluid streams are acted upon using externally applied forces including but not limited to magnetic, acoustic, heat, light, mechanical vibration, and mechanically induced deflection to produce defined features and shaping of the internal walls of the micro tubes and cavities in the cured solids.

The present invention is a method of forming an en extruded coaxial shape comprising the steps of providing a hydrodynamic nozzle, a curing system, a material bed, a control system, a gravity feed system, a fluid drain system, and simultaneously introducing a curable sheath fluid and a core ferro fluid from the hydrodynamic nozzle to form a co-flowing coaxial extrusion comprising an external sheath fluid and an internal core fluid and exposing the core fluid to a magnetic force. Depositing at least a portion of the co-flowing coaxial extrusion on the material bed and causing relative motion between the hydrodynamic nozzle and the material bed to form an extruded shape. At least partially curing a portion of the external curable fluid. Optionally introducing the co-flowing extrusion to pressure from the pressure system to remove the internal core fluid from the external curable fluid.

It is an object of the present invention to cure the tubes in free space outside of the channel versus conventional technology to cure the tubes or fibers inside of a channel.

It is an object of the present invention to cure the rely on gravity to taper and focus the internal stream to create a cylinder that is unbounded by a physical surface.

It is an object of the present invention for the gravity focusing effect to be applicable when the outer fluid necks down to a smaller diameter, whereby the present invention having a core fluid results in the fluid diameter necking down as well.

It is an object of the present invention to cure the polymer after it exists the microfluidic channel as opposed to conventional processes which cure the polymer before it exits the microfluidic channel.

It is an object of the present invention to focus the core material into very small diameters generating micron and/or submicron tubes structures, (as small as 200 nm have been achieved).

It is another object of the present invention to make tubes with core materials of larger diameters of at least up to 2 mm limited only by the nozzle design.

It is another object of the present invention to make tapered core diameters.

It is another object of the present invention to form a micro tube whereby the resulting inner diameter of the tube has a superior surface as compared to polished, drawn, traditional micro machined, injection molding, extruding and other methods (1-5 nm Ra which is a mirror finish) because the process essentially molds the sheath fluid around a core fluid and the core fluid has a very smooth surface roughness (molded parts take on the surface roughness of the molds used to make them).

It is another object of the present invention to form microsized core diameters tubes whereby the tubes can be further processed into microfluidic chips (2D networks of channels) and microfluidic bricks (3D networks of channels) by molding the tubes into a larger matrix of the UV curable material.

The present invention utilizes a ferro-fluid as the core fluid which is susceptible to magnetic fields to change the shape of the inner tube diameter. Ferro fluids are composed of very small nanoscale particles (diameter usually 10 nanometers or less) of magnetite, hematite or some other compound containing iron, and a liquid (usually oil) to disperse them evenly within a carrier fluid to contribute to the overall magnetic response of the fluid. The composition of a typical ferro fluid is about 5% magnetic solids, 10% surfactant and 85% carrier, by volume. Particles in Ferro fluids are dispersed in a liquid, often using a surfactant, and thus Ferro fluids are colloidal suspensions. True Ferro fluids are stable. This means that the solid particles do not agglomerate or phase separate even in extremely strong magnetic fields. Common ferro fluid surfactants are soapy surfactants used to coat the nanoparticles including, but are not limited to oleic acid, tetramethylammonium hydroxide, citric acid, soy lecithin, and combinations thereof. These surfactants prevent the nanoparticles from clumping together, so the particles can not fall out of suspension. The addition of surfactants (or any other foreign particles) decreases the packing density of the ferro particles while in its activated state, thus decreasing the fluid's on-state viscosity, resulting in a “softer” activated fluid. The viscosity of ferro fluid is relatively low between 1-10 centipoise. Alternatively, the present invention uses other fluids with a much higher viscosity that enables longer stable streams than lower viscosity fluids and with a specific gravity greater than that of the sheath fluid including glycerin and food products such as molasses.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

FIG. 1 shows an oblique view of a hydrodynamic nozzle assembly;

FIG. 2 shows a sectional view of a hydrodynamic nozzle assembly;

FIG. 3 shows an enlarged end view of a co-flowing extrusion formed by a hydrodynamic nozzle assembly;

FIG. 4 shows an embodiment of a machine system for forming extruded shapes;

FIG. 5 shows another embodiment of a machine system for forming extruded shapes;

FIG. 6 shows yet another embodiment of a machine system for forming extruded shapes;

FIG. 7 shows a ferro system that may be utilized by any of the embodiments shown;

FIG. 8 shows a control system used for controlling the machine system;

FIG. 9 shows a sample shape that is referenced in an example;

FIG. 10 shows a photograph of a three-dimensional shape created according certain aspects of this disclosure;

FIG. 11a is a photograph showing a top view of cured polymer and internal core cavity, a cured sheath flow, and a core cavity drained of fluid having a 30 micron diameter;

FIG. 11b is a photograph showing the change in diameter of the core fluid in the cured sheath fluid;

FIG. 12a shows a side view of the apparatus components of the invention including the funnel assembly, magnet assembly UV light assembly and substrate assembly;

FIG. 12b shows a schematic showing the process modules of FIG. 12a;

FIG. 13a shows a stage adjustment mechanism, inner nozzle, and funnel in fluid communication with the inner nozzle and the placement of the inner nozzle that deposits the core fluid (non UV-curable) into the sheath fluid;

FIG. 13b is a schematic showing the stage adjustment apparatus of FIG. 13a;

FIG. 14A shows a heated filling hose for the sheath fluid and the core fluid and the holder for the outer funnel;

FIG. 14B shows a sectional view of the core fluid flowing into the sheath fluid stream. The insert is fixed to the inner nozzle at a variable insertion distance, and the core stream may be of similar or dissimilar in diameter, and the inner nozzle can be held stationary relative to the outer nozzle which can be rotated relative to the outer nozzle body, and be concentric with or eccentric relative to the outer nozzle.

FIG. 15A is a shows the process apparatus including the motorize stage to adjust relative nozzle exit distance, the sheath fluid funnel, the core/sheath centering device, the UV curing lights (2×0, and the substrate or material bed on the xyz motor driven stages;

FIG. 15B shows an alternate assembly with additional insert that introduces two steams of core fluid into sheath fluid stream. The insert is fixed to the inner nozzle at a variable insertion distance, and the two core streams may be of similar or dissimilar in diameter, and the inner nozzle can be held stationary relative to the outer nozzle which can be rotated relative to the outer nozzle body, and ben be concentric with or eccentric relative to the outer nozzle.

FIG. 16 shows the insulated heated hose for controlling viscosity of the core and sheath fluids;

FIG. 17 shows the digital control box that controls the heated hose temperature which then sets the desired viscosity of the sheath and core fluids;

FIG. 18 shows the pressurized pot delivering sheath fluid to the funnel, the temperature control system for the sheath and core fluids, and the insulation covering;

FIG. 19 shows the insulated supply hoses for the core fluid (temperature controlled), and the syringe pump supplying the core fluid to the inside of the funnel;

FIG. 20A shows a hydrodynamic nozzle assembly with core and sheath fluid supplied to the gravity fed assembly wherein the core fluid is fed into the sheath fluid flow and the co-flowing core and sheath fluids flowing out of the exterior nozzle exit or a funnel wherein the sheath fluid is very viscous >50000 cP, while either fluid can be in a range of 1 cP up to 20,000 cP or greater;

FIG. 20B shows the nozzles of the gravity fed assembly of FIG. 20A, wherein the hydrodynamic nozzle assembly with two core fluid steams introduced into a fluid stream and blue core fluid within the clear liquid sheath fluid of FIG. 20, wherein the diameter of the sheath fluid is the same as the nozzle at the exit and quickly necks down to about 1/10 of that within a short distance and continues to taper only slightly thereafter and the using this gravity focusing effect and curing the UV curable sheath fluid, hollow tubes with inner diameters as small as 200 nm have been created;

FIG. 20C shows a sectional view of the core fluid flowing into the sheath fluid stream and the insert is fixed to the inner nozzle at a variable insertion distance, and the core stream may be of similar or dissimilar in diameter, and the inner nozzle can be held stationary relative to the outer nozzle which can be rotated relative to the outer nozzle body, and be concentric with or eccentric relative to the outer nozzle.

FIG. 21 shows a sectional view of the hydrodynamic nozzle assembly with two core fluid steams introduced into a fluid stream and blue core fluid within the clear liquid sheath fluid of FIG. 20, wherein the diameter of the sheath fluid is the same as the nozzle at the exit and quickly necks down to about 1/10 of that within a short distance and continues to taper only slightly thereafter and the using this gravity focusing effect and curing the UV curable sheath fluid, hollow tubes with inner diameters as small as 200 nm have been created;

FIG. 22 shows the end of a coaxial tube having a inner core fluid and an outer sheath fluid;

FIG. 23 is an isometric view of FIG. 22 showing the cylindrical core fluid and square sheath tube;

FIG. 24 is a plan side view of FIG. 22 showing the square sheath tube;

FIG. 25 is a sectional view of FIG. 22 showing the inner core fluid and outer sheath fluid tube and the elongated tip of the transition region;

FIG. 26 is a photograph of the microfluidic tube showing the inner core fluid and outer sheath fluid forming smooth tapered core and sheath channel about 3 inches long having a 2 mm diameter top section and 150 micron diameter bottom section formed by the gravity focusing process wherein the smooth tapered channel;

FIG. 27 shows a photograph of the microfluidic tube having a 300 micron diameter channel that has a pathway the goes over and under itself in a 3D space, and surface roughness is from 2 nm to 7 nm SA (average surface roughness);

FIG. 28 is a photograph showing a cross section of a circular channel core of ferro fluid disposed within a bulk material gravity sheath formed by an extrusion and cured by UV radiation;

FIG. 29 is a photograph showing a three dimensional pattern of a ferro fluid channel running throughout a gravity fed extrusion cured by UV radiation;

FIG. 30 shows two channel cavities formed in cured solid, whereby the multiple streams of core fluid are injected into the sheath fluid to produce multiple cavities in the cured solid; and

FIG. 31 shows the shaping of core fluid diameter and sheath fluid cavity diameter using externally applied magnetic field.

### DETAILED DESCRIPTION

The present disclosure provides a method and apparatus for forming extruded shapes having at least a hollow portion using a hydrodynamic nozzle, a curable fluid, and a focusing fluid. The extruded shapes may form a tube or plurality of tubes in a bundle or porous substrate. The ability to form concentric tubes and complex shapes provides a means forming high strength materials controlled release materials, and self-repair materials.

The apparatus comprises a hydrodynamic nozzle, a curing system, a material bed, a control system and optionally a pressure system and a fluid drain system. The method comprises simultaneously introducing a curable sheath fluid and a core fluid from the hydrodynamic nozzle to form a concentric extrusion, depositing at least a portion of the concentric extrusion on the material bed, and causing relative motion between the hydrodynamic nozzle and the material bed to form an extruded shape. The method further comprises curing or partially curing part or all of the external curable fluid. The method may optionally may introduce the concentric extrusion to pressure from the pressure system to remove the internal core fluid from the external curable fluid, and may optionally receiving the core fluid into the fluid drain system.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively. Additionally, the words “herein,” “above,” “below” and words of similar import, when used in this application, shall refer to this application as a whole and not to any particular portions of this application. When the claims use the word “or” in reference to a list of two or more items, that word covers all of the following interpretations of the word: any of the items in the list, all of the items in the list and any combination of the items in the list.

Any extruded shape, even if extruded onto a planar surface, is considered “three-dimensional” since the extrusion has a thickness, and additional process disclosed herein may cause a varying thickness.

The term “core fluid” is interchangeable with focused fluid”.

The term “sheath fluid” is interchangeable with “focusing fluid”.

### Hydrodynamic Focusing Apparatus and Method

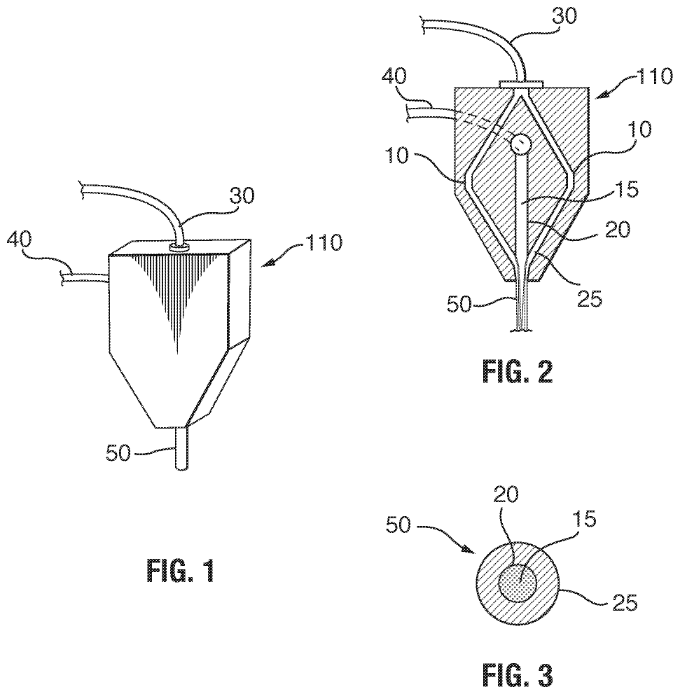

As shown in FIG. 1, a hydrodynamic nozzle assembly 110 includes a first conduit 30 and a second conduit 40, and a concentric extrusion 50 formed by the hydrodynamic nozzle assembly 110. The hydrodynamic nozzle assembly 110, as shown in FIG. 2 has the first conduit 30 supplying a sheath fluid to a sheath fluid channel 10. A second conduit 40 supplies a core fluid to the core fluid channel 20. As shown, the sheath fluid channel 10 splits into two channels near a top position, then merges to surround the core fluid channel 20 near a bottom position. This encourages laminar flow for both fluids as the fluids exit the channels. FIG. 3 shows an enlarged end view of a concentric extrusion 50 wherein the sheath fluid 25 surrounds the core fluid 15.

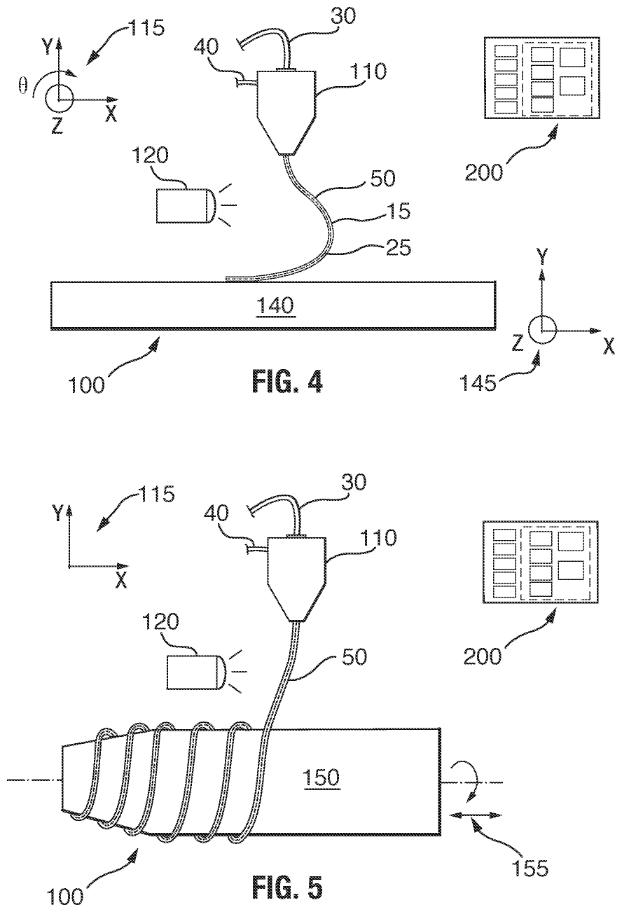

FIG. 4 shows an embodiment of a machine system 100 for forming extruded shapes. There is shown a hydrodynamic nozzle assembly 110 supplied sheath fluid 25 from a first sheath conduit 30, and core fluid 15 from a second core conduit 40. The hydrodynamic nozzle assembly 110 is configured in the machine system 100 to have an independent nozzle axis 115. As shown, there are four degrees of freedom including x-, y-, and z-translation, and θ “theta” rotation about the z-axis. Depending on the application, more or less degrees of freedom may be desired.

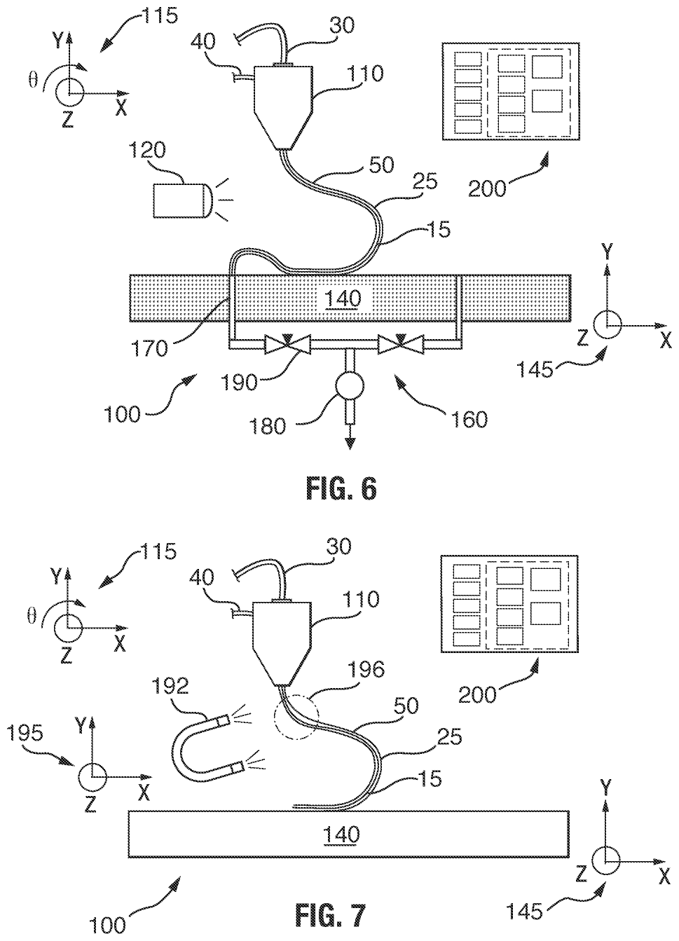

There is also shows a material bed 140 for receiving the extrusion 50. Extrusion 50 is normally flexible prior to curing. Material bed 140 provides a surface for forming 2-dimensional (2D) and three-dimensional (3D) shapes. A material bed axis 145 provides three-degrees of freedom for forming shapes from extrusion 50. These include x-, y-, and z-translation. Having two separate axes (115 and 145) enables greater flexibility in forming shapes from extrusion 50. We therefore describe motion as “relative motion” since both systems of the machine system 100, which will be described in detail with reference to FIG. 6.

FIG. 4 also shows a curing system 120. In a preferred embodiment, the curing system 120 is an ultraviolet (UV) system that is capable of rapidly curing a UV-responsive sheath material such as SR399 which is a dipentaerythritol pentaacrylate (DPHPA).

A UV curing system 120 surrounds the extrusion 50 during curing to provide rapid and uniform curing. An example of a UV surround system is to use reflectors to surround a single UV source. The reflectors may be positioned to redirect UV energy uniformly around the extrusion 50. In another example, a UV ring light, which normally consists of a series of UV LEDs positioned in a doughnut shape, may be used. One example of a UV ring light is a VISILED UV ring light available from Schott (www.schott.com). A combination of UV lights may provide partial curing near the hydrodynamic nozzle assembly 110 by, for example, a UV ring light, and one or more additional UV lights directed to the final shape that may be positioned on a material bed 140. Material bed 140 may be metal, polymeric, glass, silicon wafer, or any suitable surface. The material bed 140 may include threaded holes for attaching special fixtures which may be used to make specific shapes. One or more portions of material bed 140 may also be transparent or translucent to provide for additional UV lights to minimize any shadow areas, thereby enabling uniform UV curing of extrusion 50.

An extruded shape that is at least partially cured in situ may be created in free space, wherein a shape may be extruded to make contact with the material bed 140 but then be moved away from the material bed 140 in a (y-direction), translated in an x- or z-direction in free space, then again making contact with the material bed 140.

FIG. 5 shows an alternate embodiment of a machine system 100 for receiving extrusion 50 for forming shapes. In this embodiment, a mandrel 150 may receive extrusion 50. The mandrel 150 is controlled by mandrel axis 155, which provides rotation about a central axis, and may also provide axial translation. The mandrel may be cylindrical, conical, or may include an offset axis for forming complex rotation-based shapes. Shown in FIG. 5, are protrusions to anchor the leading end of the extrusion 50 prior to rotating. Coordination of the mandrel axis 155 with the nozzle axis 115 is performed by the control system 200. A curing system 120 such as shown in FIG. 4 may be used to cure extrusion 50. The mandrel 150 may be at least partially transparent or translucent and fitted with UV lights to reduce shadow areas for uniform UV curing.

For certain core fluids or certain shapes, the core fluid 15 used in the production of a concentric extrusion 50 requires removal. In some scenarios, the final shape may be cured, trimmed if needed, and any core fluid 15 may be removed using manual methods. In other scenarios, however, auto-removal of the core fluid 15 may be preferred. FIG. 6 shows another alternate embodiment of a machine system 100 for receiving extrusion 50 for forming shapes. In this embodiment, material bed 140 includes a fluid removal system 160.

Fluid removal system 160 is comprised of at least one fluid port 170 that is exposed to the top surface (as shown) of the material bed 140. A pressure system 180 enables positive or negative pressure to be applied. If more than one fluid port 170 is included, valves 190 enable pressure (positive or negative) to be applied only to the fluid port 170 that is in fluidic communication with the extrusion 50. By closing valves that are in fluid communication with any open fluid ports 170, pressure can be more efficiently directed to the extrusion 50. For some extrusions 50 that are extremely flexible, it may be preferred to at least partially cure the extrusion 50 prior to removing the core fluid 25 to avoid inflating (if positive pressure is used) or collapsing (if negative pressure is used) the extrusion 50.

In operation, the leading end of the extrusion 50 is placed in fluid communication with a fluid port 170 prior to shape formation. Curing or partial curing may occur during extrusion. Once the extrusion 50 is completed and has been severed from the hydrodynamic nozzle assembly 110, pressure may be applied using the pressure system 130. It is preferred that the severed end of the extrusion 50 be at least partially opened during application of pressure.

In FIG. 7, there is shown an additional feature that may improve the functionality of any of the preceding embodiments. A ferro system 192 is shown in simplified form, which may be used in cooperation with a magneto rheological or other responsive fluid such as an electro rheological fluid hereinafter “smart fluid” as the core fluid 15. The ferro system 192 may be a permanent magnet or electro-magnet that is capable of shaping the extrusion 50 by changing its position or cross-section acting on the ferro fluid as the core fluid 15. The ferro system 192 is controlled by ferro axis 195, which may provide rotation and translation of the ferro system 192. By using a smart fluid, the apparent viscosity can be changed by the application of a magnetic or electric field, creating a flow change and therefore shape change in the core fluid. Combining and diverging the core streams allow for a wide range of shape adjustments to the extruded shape.

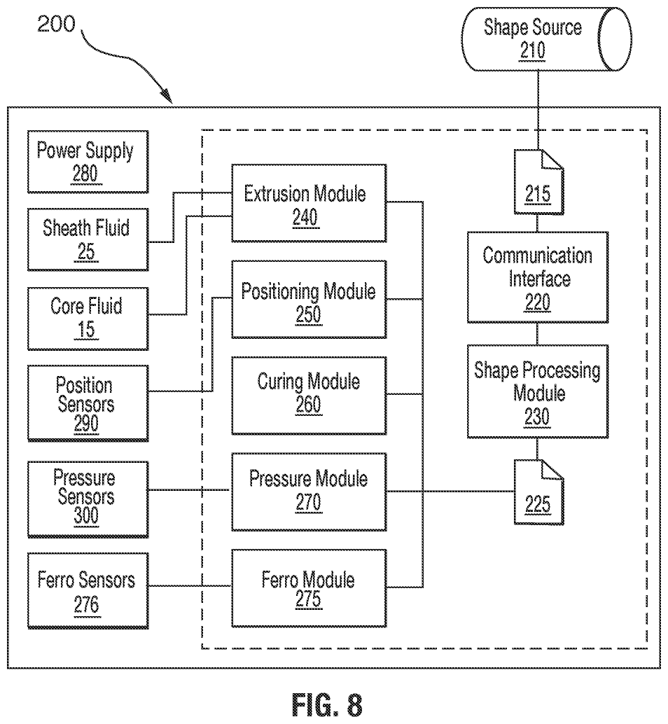

The control system 200 shown in FIG. 8 is supplied power by a power supply 280. The control system 200 may include a communication interface or module 220 coupled to a shape processing module 230. The shape processing module 230 may be communicatively coupled to an extrusion module 240, a positioning module, 250, a curing module 260, a pressure module 270, and a ferro module 275.

The shape source 210 may be any type of device capable of transmitting data related to a shape file to be formed by machine system 100 in cooperation with the shape processing module 230. The shape source 210 may include a general-purpose computing device, e.g., a desktop computing device, a laptop computing device, a mobile computing device, a personal digital assistant, a cellular phone, etc. or it may be a removable storage device, e.g., a flash memory data storage device, designed to store data such as shape data. If, for example, the shape source 210 is a removable storage device, e.g., a universal serial bus (USB) storage device, the communication interface 220 may include a port, e.g., a USB port, to engage and communicatively receive the storage device. In another embodiment, the communication interface 220 may include a wireless transceiver to allow for the wireless communication of shape data 215 between the shape source 210 and the control system 200. Alternatively, the communication interface 220 may facilitate creation of an infrared (IR) communication link, a radio-frequency (RF) communication link or any other known or contemplated communication system, method or medium.

The communication interface 220 may be configured to communicate with the shape source 210 through one or more wired and/or wireless networks. The networks may include, for example, a personal area network (PAN), a local area network (LAN), a wireless local area network (WLAN), a wide area network (WAN), etc. The networks may be established in accordance with any number of standards and/or specifications such as, for example, IEEE 802.11x (where x indicates a, b, g and n, etc.), 802.16, 802.15.4, Bluetooth, Global System for Mobile Communications (GSM), code-division multiple access (CDMA), Ethernet, etc.

The shape processing module 230 may receive the shape data 215 from the communication interface 220 and process the received shape data 215 to create a shape job 225 for use within the machine system 100. Alternatively, the processing of the shape data 215 may be performed by the shape source 210 or other device or module and the resulting shape job 225 may be communicated to the communication interface 220. The processed shape data 215 and/or shape job 225 may, in turn, be provided to the shape processing module 230. The shape processing module 230 can cache or store the processed shape data 215 or may communicate the shape data 215 in real-time for shape job 225 creation.

The shape processing module 230 sends the shape job 225 to the extrusion module 240, positioning module 250, curing module 260, and optionally the pressure module 270 if using a pressure system 180 with the material bed 140, and optionally the ferro module 275 if ferro fluid is used as the core fluid 15. The extrusion module 240 controls the extrusion parameters based on material properties of the sheath fluid 15 and core fluid 15, and desired shape outcome. The extrusion module 240 is configured to cooperate with positioning module 250, which includes positioning data for the nozzle axis 115 and material bed axis 145. Alternately, if the mandrel 150 is used instead of the material bed 140, the positioning module 250 includes positioning data for the nozzle axis 115 and mandrel axis 155. Position sensors 290 provide feedback for closed-loop location information. Sample position sensors 290 include optical encoders (not shown) that may be linear or rotary strips having scale markings that are detected by optical sensors. An analog or digital signal may provide position feedback based on the number of scale markings detected by the optical sensors. Pressure module 270 receives information from the shape processing module 230 whether core fluid 15 will be removed by pressure or not. If core fluid 15 is to be removed, the magnitude and direction of pressure (such as low vacuum pressure or moderate positive pressure) will be determined based on the anticipated properties of the extrusion 50 at the time pressure is to be applied. The pressure module 270 will also control any valves 190 if multiple fluid ports are available for use. If there is only one fluid port, there is no need for valves 190. The control system also controls the temperature of fluids, and therefore the viscosity of the fluids.

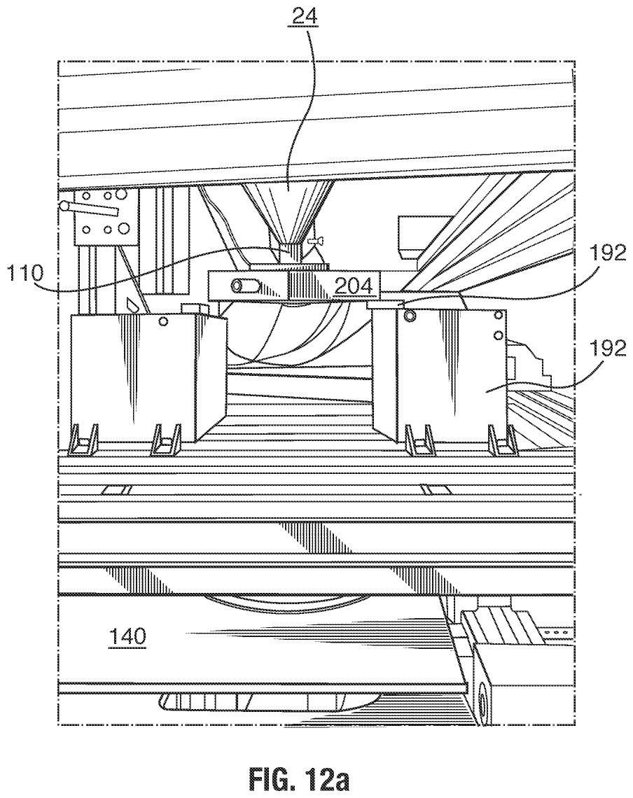

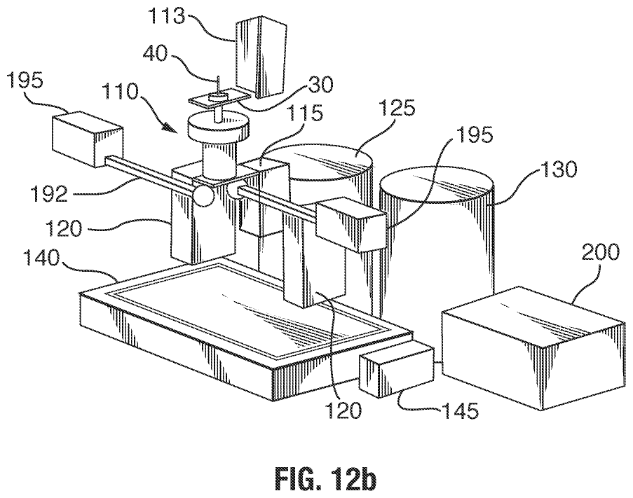

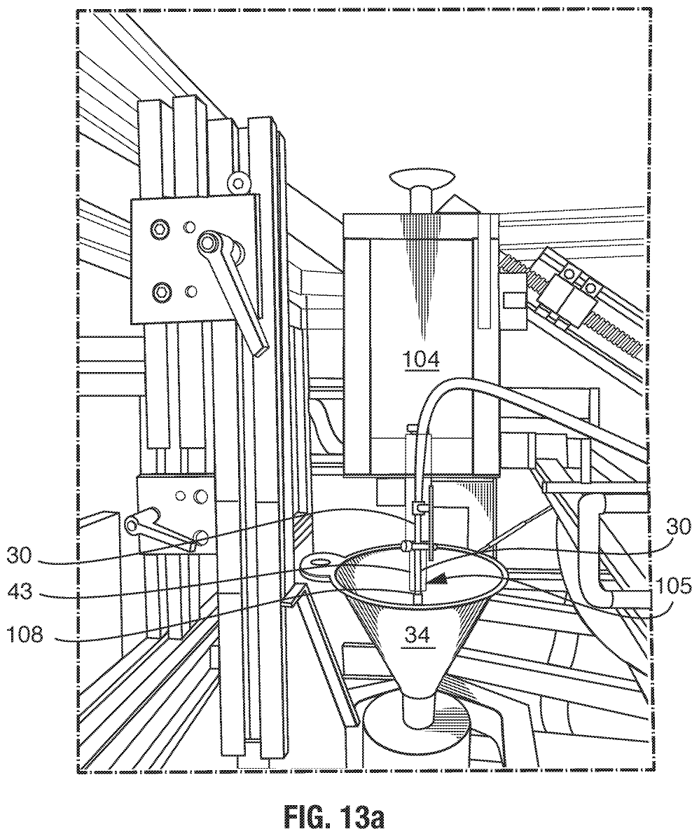

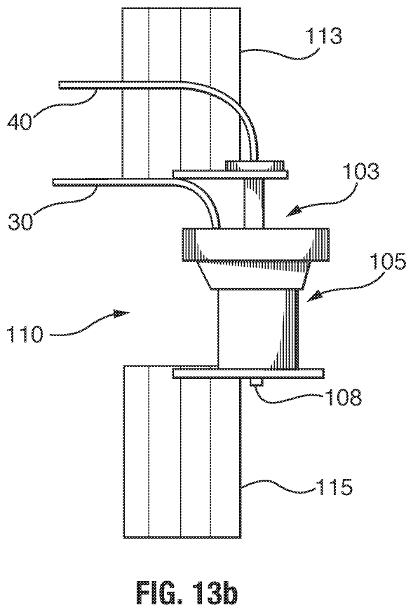

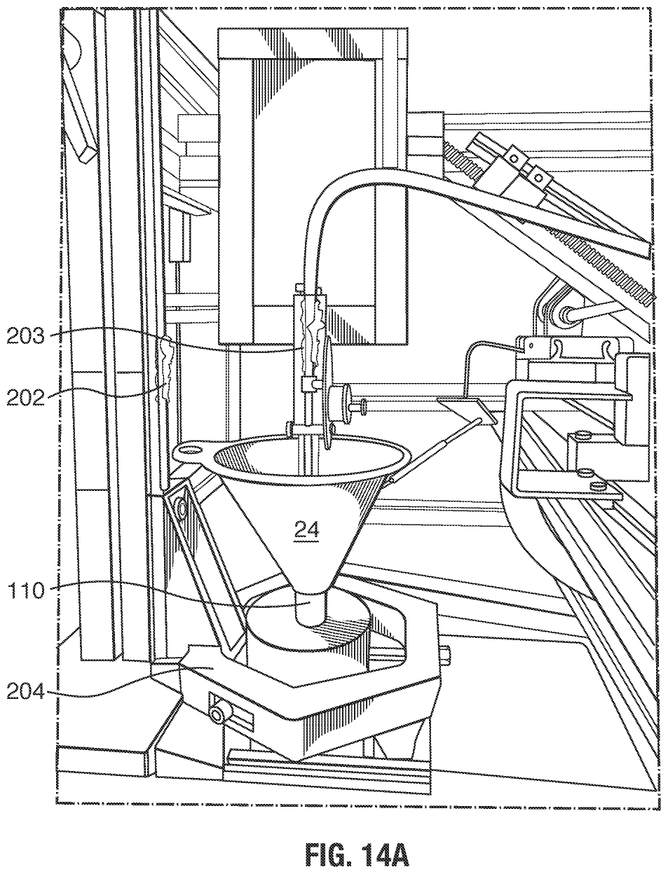

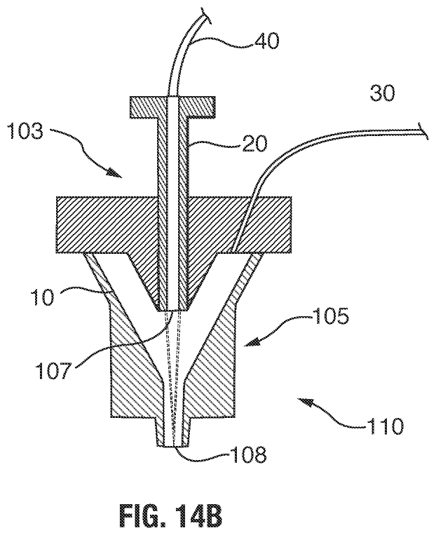

As shown in FIG. 12, the apparatus components of the invention include a hydrodynamic nozzle assembly 110, ferro system 192, curing system 120, and material bed 140. More particularly, the hydrodynamic nozzle assembly 110 includes an outer nozzle assembly 105 containing the sheath fluid 25 with an inner nozzle assembly 103 that delivers the core fluid 15, as shown in FIGS. 13 and 14. Both fluids then exit the outer nozzle exit 108 together and both fluids are reduced in diameter due to the gravity focusing effect. Permanent magnets are used (it is anticipated electromagnets in the ferro system 192 can be used as well) when a ferro-fluid is the core fluid 15 to change the shape of the inner tube diameter. An effective amount of curing radiation from UV curing lights have 405 nm wavelength to cure the falling sheath fluid is use as the curing system 120 for the duration necessary. Light sources of other wavelengths are anticipated for alternative sheath fluids 25. The material bed 140 is position controlled by material bed axis 145 (xyz stage motion) to catch the cured CO-flow extrusion 50 and/or allow build up and different channel patterns (3D).

FIGS. 13 and 14 show the inner nozzle assembly 103 and outer nozzle assembly 105 collectively hydrodynamic nozzle assembly 110 with dependent nozzle axis 113 and independent nozzle axis 115. Moreover, the dependent nozzle axis 113 adjust the position of the inner nozzle exit 107 to the outer nozzle exit 108. The inner nozzle assembly 103 deposits the core fluid 15 into the sheath fluid 25 flow. The distance between the inner nozzle exit 107 and the outer nozzle exit 108 is a key facto r in determining the interaction of the core fluid 15 and sheath fluid 25 to create the fluid focusing effect.

FIGS. 13a and 13b also shows how the stage 104 adjusts the distance from the inner nozzle exit to the outer nozzle exit. The inner nozzle that deposits the core fluid is a key parameter and controls the distance of the inner nozzle to the exit of the funnel outer nozzle. The funnel 24 containing the sheath fluid 25 (UV curable) is shown that the placement of the inner nozzle that deposits the core fluid 15 (non-UV curable fluid into the sheath fluid 25.

Temperature controlled first sheath conduit 30 and second core conduit 40 deliver the sheath fluid 25 and core fluid 15 respectively from sheath fluid supply 125 and core fluid 130 to the hydrodynamic nozzle assembly 110. Viscosity of the fluids is lowered by heating and increased by cooling. FIG. 14A shows the heated filling hoses for the sheath fluid and core fluid. The higher the viscosity the longer the manufactured tube body. The lower the viscosity, the less bubbles are produced in the tube body. The holder 204 provides adjustment of the dependent nozzle axis 113 and can also be used to locate the center of the core fluid 15 relative to the center of the sheath fluid 25 so the inner and outer diameters of the manufactured tube will be concentric or eccentric with respect to each other.

As shown in FIG. 12a, the funnel contains the sheath fluid 25 with a nozzle on the inside that delivers the core fluid 15. Both fluids then exit the nozzle of the funnel together coaxially and both fluids are reduced in diameter due to the gravity focusing effect. Permanent magnet used when one uses a ferro fluid as the core fluid is greater when use do change the shape of the inner tube diameter. UV curing light with 405 nm wavelength can be used to cure the falling sheath fluid 25 in one preferred embodiment. A material bed such as a substrate mounted onto a movable drive (xyz stage motion) to catch the cured stream and/or to allow build up and a different channel to create patterns.

By controlling the core fluid 15 and sheath fluid 25 volume flow rates, the dimensions of the extrusions can be altered without the application of physical changes to the apparatus.

Figure shows an embodiment of a hydrodynamic nozzle assembly 110. There is shown a first conduit 30 and a second conduit 40 and a co-flowing extrusion 50 formed by the hydrodynamic nozzle assembly 110.

FIG. 2 shows a sectional view of the hydrodynamic nozzle assembly 110 of FIG. 1. A first conduit 30 supplies a sheath fluid 25 to a sheath fluid channel 10. A second conduit 40 supplies a core fluid 15 to the core fluid channel 20. The sheath fluid channel 10 splits into two channels near a top position, then merges to surround the core fluid channel 20 near a bottom position. This encourages laminar flow for both fluids as extrusion 50 exists the outer nozzle 108. The sheath fluid channel forms a chamber surrounding the core fluid channel 20 to achieve the same encouragement of laminar co-flow of the fluids as shown in FIG. 3.

FIG. 14A shows the heated filling hose for the sheath fluid and the core fluid and 14B shows details of the hydrodynamic nozzle assembly 110. Heating the core and sheath tube conduits controls the viscosity of the fluids. The higher the viscosity the longer the manufactured tubes. The lower the viscosity, the less bubbles that result in the manufactured tube body. Also, shown is the holder for the outer funnel. It is adjustable in the x and y directions so as to make sure the inner nozzle is perfectly centered in the outer funnel nozzle. That way the core fluid 15 stream is centered in the sheath fluid 25 stream such that the inner and outer diameters of the manufactured tubes are concentric. FIG. 14A also shows a heated filling hose 202 for the core fluid and heated core filling hose 203. Hating the hose controls the viscosity of the fluids. Higher viscosity forms longer manufactured tubes. Lowering the viscosity decreases the amount of bubbles that could form in the tube body. The holder 204 is shown holding the outer funnel 24. It is adjustable in the x and y directions so as to make sure the inner nozzle is perfectly centered in the outer funnel nozzle so the core stream is centered in the sheath stream to form concentric inner and outer diameters of the tubes.

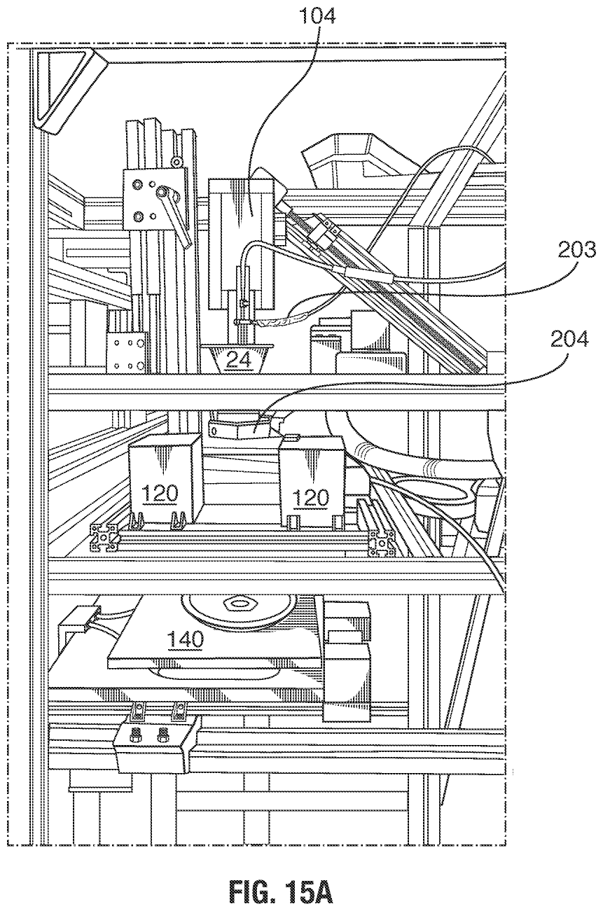

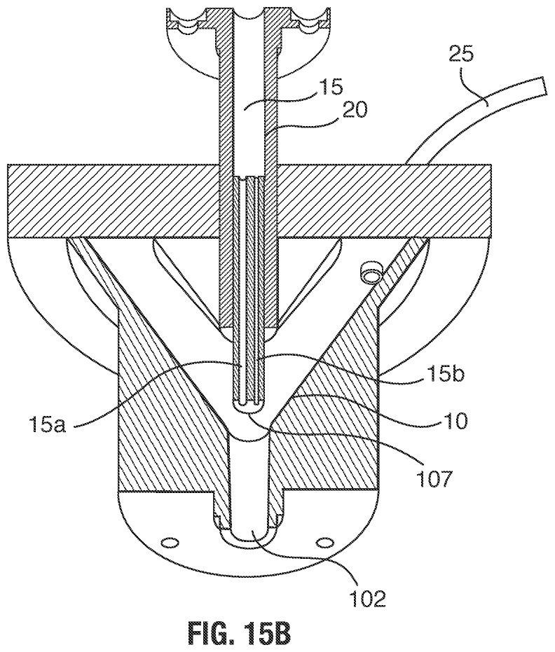

FIG. 15A shows the process apparatus including the motorized stage 104 to adjust relative nozzle exit distance, the sheath fluid funnel 24, the core/sheath centering device 204, the UV curing lights (2×0) 120, and the substrate or material bed 140 on the xyz motor driven stages;

FIG. 15B shows an alternate assembly with additional insert that introduces two steams of core fluid 15A and 15B into sheath fluid stream. The insert is fixed to the inner nozzle at a variable insertion distance, and the two core streams may be of similar or dissimilar in diameter, and the inner nozzle exit 107 can be held stationary relative to the outer nozzle 108 which can be rotated relative to the outer nozzle body 109 and be concentric with or eccentric relative to the outer nozzle 108.

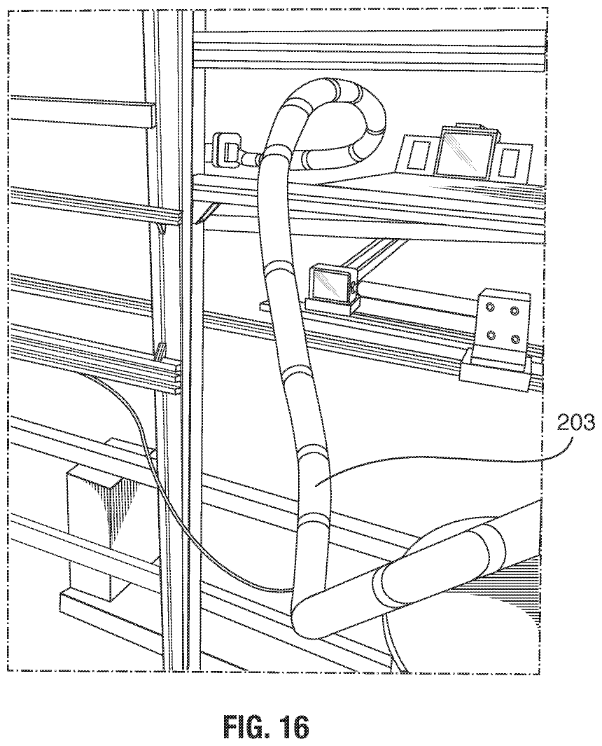

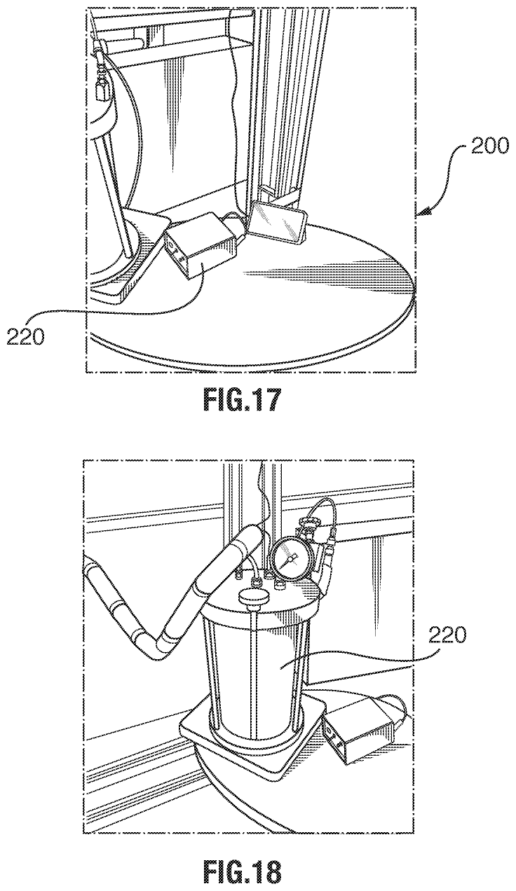

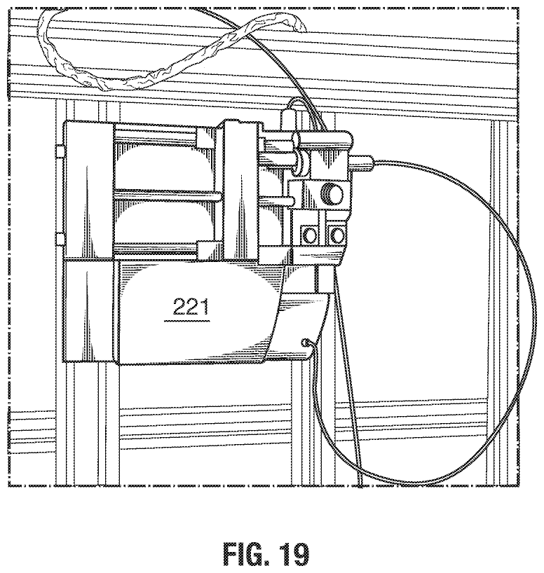

FIG. 16 shows the insulated heated hose 203 for controlling viscosity of the core and sheath fluids; FIG. 17 shows the digital control box 220 that controls the heated hose temperature which then sets the desired viscosity of the sheath and core fluids; FIG. 18 shows the pressurized pot 219 for delivering sheath fluid to the funnel, the temperature control system for the sheath and core fluids, and the insulation covering; and FIG. 19 shows the insulated supply hoses for the core fluid (temperature controlled), and the syringe pump 221 supplying the core fluid to the inside of the funnel.

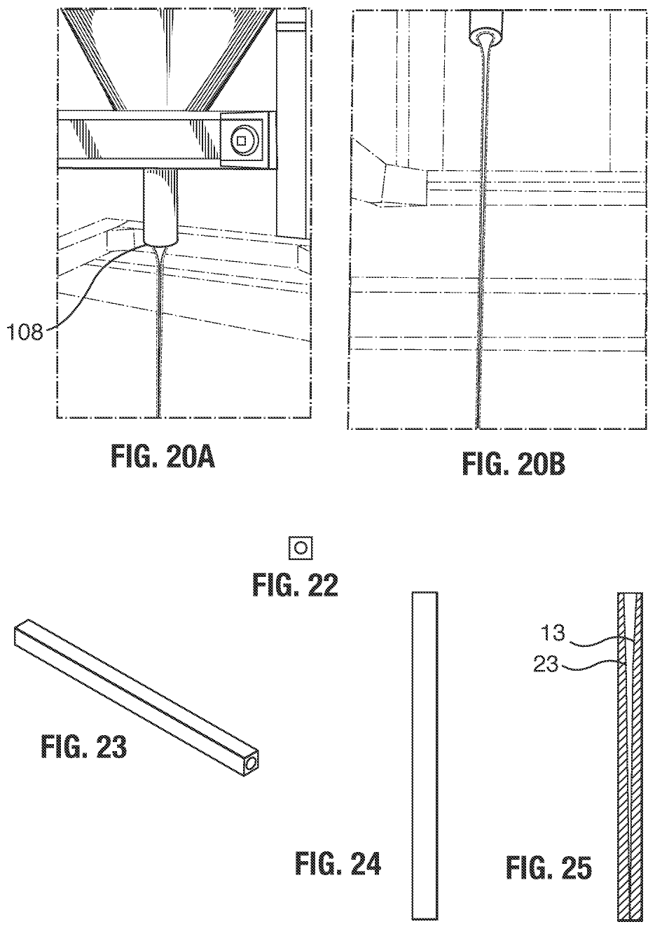

FIG. 20A shows a hydrodynamic nozzle assembly 110 with core 15 and sheath fluid 25 supplied to the gravity fed assembly wherein the core fluid 15 is fed into the sheath fluid flow and the coaxial core and sheath fluids 37 co-flowing out of the exterior nozzle exit 108 or a funnel wherein the sheath fluid is very viscous >50000 cP, while either fluid can be in a range of 1 cP up to 20,000 cP or greater. FIGS. 20B and 20C show the nozzle of the gravity fed assembly of FIG. 20A and view of the co-flowing tapered coaxial core and sheath fluid 37 exiting the nozzle.

The hydrodynamic nozzle assembly 110 has a core fluid steam 15 introduced into a clear sheath fluid stream 25 wherein the blue core fluid 15 is surrounded by the clear liquid sheath fluid 25. The diameter of the sheath fluid 25 is the same as the nozzle at the nozzle exit 108 and quickly necks down to about 1/10 of that within a short distance and both the core fluid 15 and coaxial sheath fluid 25 continue to taper only slightly thereafter and the using this gravity focusing effect and curing the UV curable sheath fluid, hollow tubes with inner diameters as small as 200 nm have been created.

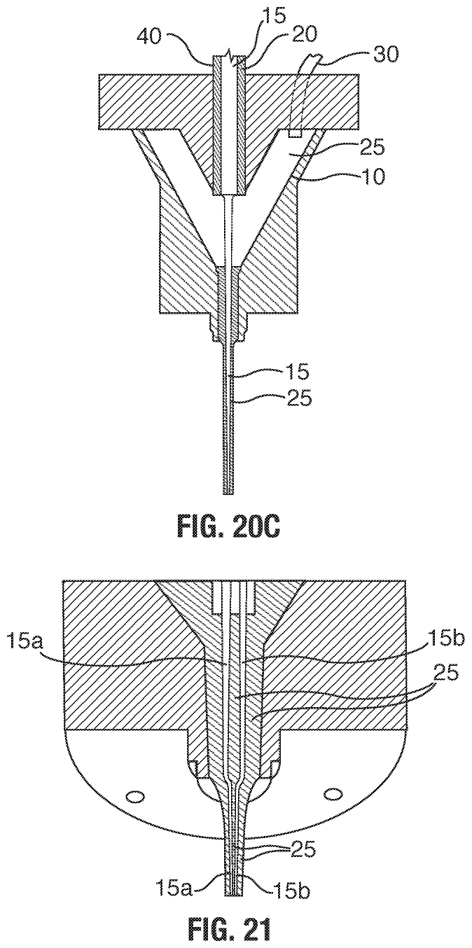

FIG. 21 shows a gravity fed assembly nozzle of FIG. 20C in cross section with two core streams.

FIG. 22 shows the end of a coaxial tube formed in a block having a inner core fluid and an outer sheath fluid; FIG. 23 is an isometric view of FIG. 22 showing the cylindrical core fluid and square sheath tube; FIG. 24 is a plan side view of FIG. 22 showing the square sheath tube; and FIG. 25 is a sectional view of FIG. 22 showing the inner core fluid and outer sheath fluid tube and the elongated tip of the transition region.

The following examples describe preferred embodiments of the intention. Other embodiments within the scope of the claims herein will be apparent to one skilled in the art from consideration of the specification or practice of the invention as disclosed herein. It is intended that the specification, together with the examples, be considered exemplary only, with the scope and spirit of the intention being indicated by the claims which follow the examples. The present disclosure will be more readily appreciated with reference to the example which follows.

### Example 1

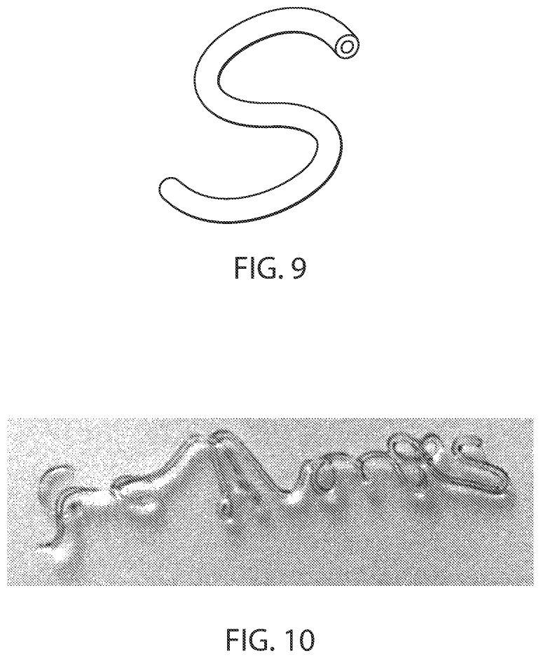

An extruded shape in the form of an “S” is desired which is shown in FIG. 9. The “S” is 40 mm in height, and 27 mm in width. The thickness (outer diameter of the extrusion) is 1 mm (1,000 microns). The sheath fluid 25 used is a polyacrylate. The core fluid 15 is water. The inner diameter of the sheath fluid is 0.5 mm (500 microns). The shape will be trimmed manually after curing. Since water is used as a core fluid, and the inner diameter of the shape is sufficiently large so that capillary retention of the core fluid should be minimal, the automated pressure module 270 will not be requested.

The sheath fluid 25 is capable of being partially cured using typical curing wavelengths. The curing system 120 is a 35-watt UV LED light ring attached to the hydrodynamic nozzle assembly 110. The material bed 140 includes a top surface of transparent glass. Below the material bed 140 is a 35-watt UV LED array. The extruded shape was drawn and converted to a vector file, which is the shape data 215. The shape data 215 was received by the communication interface 220 and sent to the shape processing module 230 for processing into a shape job 225. The shape job 225 was sent to the extrusion module 240, the positioning module 250, and the curing module 260.

The machine system 100 was then activated, the hydrodynamic nozzle assembly 110 was preheated to 100° F. (37.8° C.), and sheath fluid 25 and core fluid 15 were introduced to the hydrodynamic nozzle assembly 110 via first conduit 30 and second conduit 40, respectively. The hydrodynamic nozzle assembly 110 moved to a close proximity (within 25 mm) to the material bed 140, which is planar. Extrusion from the hydrodynamic nozzle assembly 110 was activated, and the nozzle axis 115 and material bed axis cooperated to produce relative motion between the hydrodynamic nozzle assembly 110 and the material bed 140 that resulted in an “S” shape being extruded onto the material bed 140. After extrusion, the hydrodynamic nozzle assembly 110 was moved to a central position above the shape, and the curing system 120 was activated. Both the UV LED light ring and the UV LED array were activated simultaneously for 12 seconds (10 seconds minimum and a safety margin of 2 seconds). After 12 seconds, the curing system 120 was deactivated, and the hydrodynamic nozzle assembly 110 and the material bed 140 were returned to a home position, enabling the user to manually remove the shape for trimming and removal of the core fluid 15.

### Example 2

The sheath fluid 25 used was a polyacrylate. The core fluid 15 was water The inner diameter of the sheath fluid was 0.03 mm (30 microns). A random three-dimensional shape was created according to aspects of the present disclosure. See FIG. 10.

### Example 3

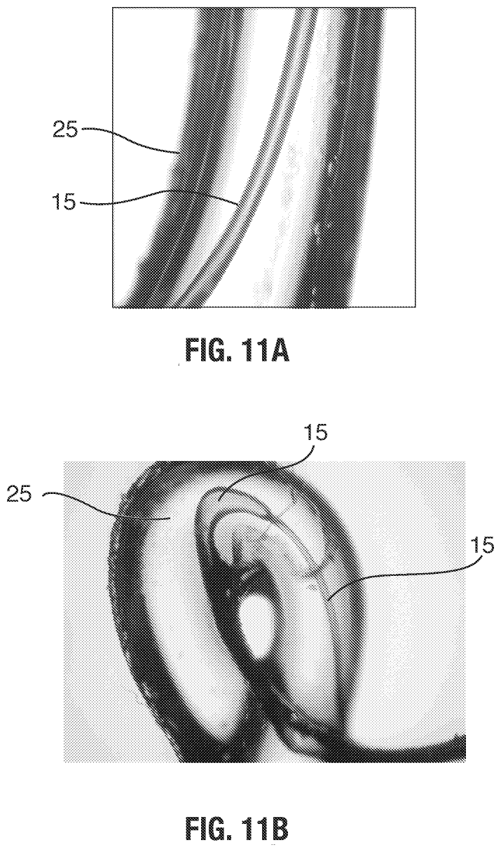

The sheath fluid 25 used was a dipentaerythritol pentaacrylate. The core fluid 15 was an electro rheological fluid EMG 700 from Ferrotec USA Corporation, located in Santa Clara, Calif. The inner diameter of the sheath fluid was 0.03 mm (30 microns). A random three-dimensional shape was created according to aspects of the present disclosure. See FIG. 11a showing a top view of cured polymer and internal core cavity with the outer layer showing the cured sheath flow and the core cavity, shown as a tube drained of fluid having a 30 micron diameter. FIG. 11b shows the change in the diameter of the core fluid in the cured sheath.

### Manufacture of Tubular Plastic Using Body Force Focusing (Gravity Focusing)

This method uses co-flow of two immiscible fluids that exit a nozzle, chute, ledge, beaker edge or the like (all termed “outer nozzle exit”), simultaneously, and one totally encased by the other, but not necessarily at the same flow rates. The motive force for the co-flowing fluids from the outer nozzle exit may be gravity, centrifugal force or any other body force generation method. The outer fluid is termed the sheath fluid and the inner fluid is termed the core fluid. A distinguishing characteristic of the flow from the outer nozzle exit is that the diameter or width of sheath fluid is reduced as it exits the outer nozzle exit. The core fluid, likewise, is reduced in width or diameter. This reduction in width or diameter is commonly termed “focusing”, and the motive force is a body force, like gravity, it is further termed “gravity focusing”. Gravity focusing is distinguished from the commonly used method of hydrodynamic focusing in that, hydrodynamic focusing generates co-flow from a nozzle into a constrained channel, whereas gravity focusing generates co-flow from a nozzle into unconstrained free space. A further distinguishing factor is that hydrodynamic focusing relies on surface forces (like applied pressure) to force the sheath and core fluids through converging interior nozzles to provide focusing, whereas gravity focusing relies upon the body force of gravity, the initial geometry of the nozzle assembly, the sheath fluid 25 and core fluid 15 viscosities and the surface tension between the outer nozzle exit and sheath fluid at the outer nozzle exit to provide fluid focusing.

The flow of material for a gravity focusing system is characterized by the jet shape and depends on the dynamic viscosity of the Newtonian fluid typically forming a concave jet, flow velocity at the outer nozzle exit resulting in a straight, vertical shape, falling height forming a vertical jet, and the flow of material application onto a moving substrate whereby the flow of material forms a convex shape.

This method presented here further relies on the sheath fluid 25 being comprised of a fast curing, liquid plastic that can be cured by different means but preferentially using ultra-violet light as a curing system 120, with the core fluid 15 being non-curable or remaining free flowing, but immiscible with the sheath fluid 25, so as the two fluids remain co-flowing and do not mix as the co-flowing extrusion 50 jet travels away from the outer nozzle exit. The curing system 120 is positioned at a selected distance below the outer nozzle exit 108 and some distance away from the co-flowing sheath fluid 25 and core fluid 15. The exact distances depend upon the tubular geometry desired. As the co-flowing extrusion 50 passes through the UV curing system 120, the curing system is activated such that the sheath fluid 25 is cured into a solid plastic material. That material is then removed either as a discrete part or spooled onto a mandrel in a continuous fashion, depending upon the tube design objectives. The core fluid 15 may remain inside the tube, may be cleaned out of the tube may be replaced by another material inside the tube depending upon the design and use intent.

This method has advantages over other tube making methods in that it can be used to focus the core sheath 25 into very small diameters (as small as 200 nm have been achieved). It can be used to make tubes with core fluids 15 of larger diameters, limited only by the hydrodynamic nozzle assembly. Micro tubes at least up to 2 mm in diameter has been achieved and the tubes can be made with tapered core diameters. Furthermore a plurality of micro tubes can be bundled for higher flow rate and/or surface area in fluidic applications or flow rate. The resulting inner diameter of the tube has a superior surface as compared to polished, drawn, traditional micro machined, injection molded, extruded and other fabrication methods and potentially providing a smooth surface of (1-5 nm Ra which is a mirror finish) because the process essentially molds the sheath fluid 25 around a core fluid 15 and the core fluid 15 has a very smooth surface roughness (molded parts take on the surface roughness of the molds used to make them). Upon forming microsized core diameters, the tubes can be further processed into microfluidic chips (2D networks of channels) and microfluidic bricks (3D networks of channels) by molding the tubes into a larger matrix of the UV curable material.

### Example 4

A 100 mL beaker with approximately 25 mL of highly viscous, UV curable sheath fluid 25 material and 5 mL of significantly less viscous core fluid 151 was used where the core fluid 15 specific gravity is greater than that of the sheath fluid 25 such that it remains inside the sheath fluid 25 as a ball of material (doesn't float to the top and spread out). The beaker was simply tilted by manually such that the sheath fluid 25 began to flow over the edge of the beaker spout acting as a outer nozzle exit and the flow of the sheath fluid 25 began to draw from the ball of the core fluid 15 until a small stream of the core fluid 15 formed on the inside of the sheath fluid 25, both fluids co-flowing over the edge of the beaker. Due to the high viscosity and surface tension of the sheath fluid 25, a significantly tapered flow was seen from the outer nozzle exit 108 formed by the beaker spout to the free stream extrusion 50. A hand-held radiation device, such as a UV light, was used to cure the sheath fluid 25 just prior to it collecting onto a substrate such as a material bed, resulting in solid diameters of plastic tubing with micro sized inner diameters.

The plastic tubing was then cast into a larger chip of UV cured material and the inner channels were accessed by drilling and then gluing connectors in place. In this manner a microfluidic flow chip of 3D nature was created.

A funnel outlet or an L-shaped or C-shaped chute can be utilized as the outer nozzle exit 108. The sheath fluid 25 is maintained in the funnel or chute using a syringe pump or a pressurized pot with a hose. The core fluid 15 is injected into the sheath fluid 25 using a syringe pump with a syringe and a dispense tip or syringe needle as the inner nozzle assembly 103, depending upon the design intent. As the co-flowing fluids are extruded from the outer nozzle assembly 108, UV curing lamps act as the curing system 120 and are actuated by the curing module 260 to cure the sheath fluid 25. The material either collects onto a material bed 140 or is captured in free space and removed as a discrete tubular section. A mandrel, (not yet implemented in an automated fashion), can be used to collect the tubular section in a continuous fashion to create very long tubes of several feet in length and the length is limited only by the length of the mandrel.

FIGS. 20 and 21 shows a gravity fed hydrodynamic nozzle assembly 110 having a blue core fluid within a clear liquid sheath fluid 25 extending from the outer nozzle exit “funnel”. The sheath fluid 25 is very viscous, greater than 5000 centipoise. Either fluid can be in a range of 1 cP (like water) up to 20,000 centipoise or greater (2-3 times the viscosity of honey). The gravity focusing effect is seen for both fluids as the outer diameter of the sheath fluid 25 is that of the outer nozzle exit 108 and it quickly necks down to about 1/20 of that within a small distance. The co-flowing extrusion 50 continues to taper but only slightly at distances away from the nozzle. Using this gravity focusing effect and curing the UV curable sheath fluid 25, hollow tubes have been formed with inner diameters as small as 200 nanometers.

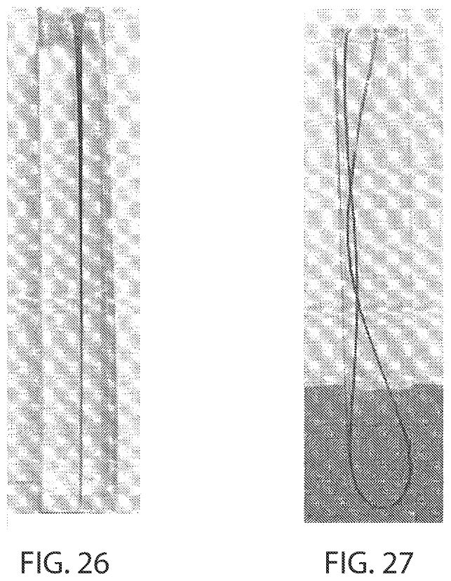

As illustrated in FIG. 26 is a microfluidic tube having a smooth tapered channel with a 2 mm diameter to section and a 150 micron diameter bottom section about 3 inches long produced by a gravity focusing process. A microfluidic tube having a smooth tapered channel with a 300 micron diameter channel that has a pathway that goes over and under itself in a 3D space (10 mm×10 mm×70 mm) produced by a gravity focusing process is shown in FIG. 27. Minimum tapered diameters are about 200 nm and maximum tapered diameters are about 3 mm. Surface roughness range measured for the channel surfaces range from 2 nm to 7 nm Sa (average surface roughness).

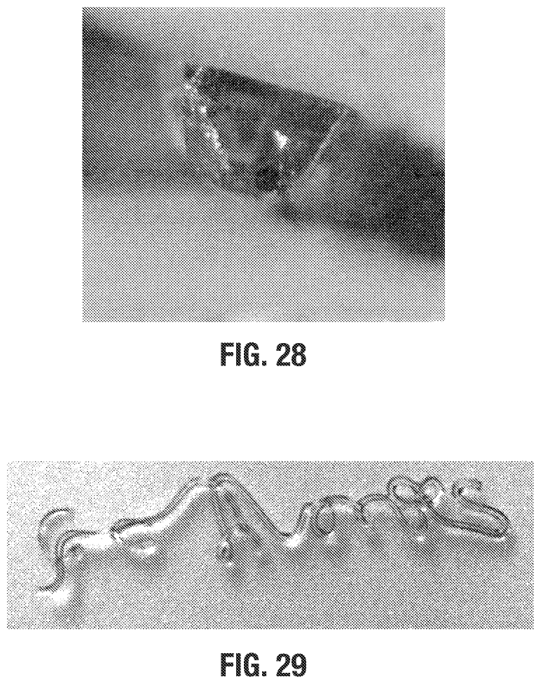

Gravity fed extrusion of SR399 and ferro fluid, is cured as it takes shape as shown in FIGS. 28 and 10. The external three dimensional pattern is controlled by the pouring/dispensing pattern and fast curing of the extrusions, while the internal three dimensional pattern of the channels is shaped by the volume and speed of the feed, as well as magnetics. The combination of these forces allows for true 3-dimensional formations. Without the influence of magnetics, the resulting ferro fluid channels are circular. Adjusting the rate of flow and the volume of ferro fluid in the flow changes the diameter of the channels. Addition of magnetic forces also alters the diameter and path of the ferro fluid. The practice works by hydrodynamic focusing of the ferro fluid, aided by the immiscibility of the ferro fluid with the surround monomer. This fabrication method also applies to continuous extrusion of tubing as shown in FIGS. 4, 5, 6, 7, and 9.

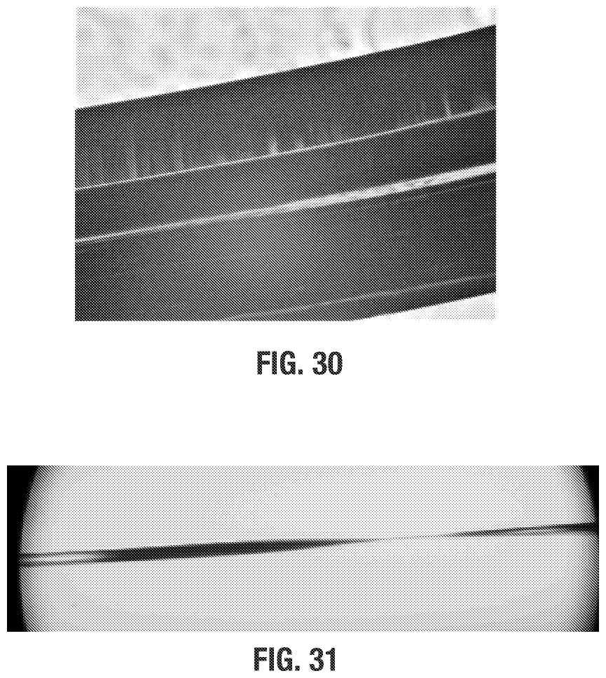

Fluid streams are acted upon using other process manipulations, as well as externally applied forces (including, but not limited to, magnetic, mechanical vibration used in fabrication, and mechanically induced deflection used in fabrication) to produce defined features and shaping of the cavities in the cured solid. FIG. 30 shows two channel cavities formed in cured solid, whereby the multiple streams of core fluid are injected into the sheath fluid to produce multiple cavities. FIG. 31 shows the shaping of cavity diameter using externally applied magnetic field.

It is contemplated and will be clear to those skilled in the art that modifications and/or changes may be made to the embodiments of the disclosure. Accordingly, the foregoing description and the accompanying drawings are intended to be illustrative of the example embodiments only and not limiting thereto, in which the true spirit and scope of the present disclosure is determined by reference to the appended claims.

1. A method for forming an extruded shape, comprising the steps of:
a) providing a hydrodynamic nozzle;
b) providing a curing system;
c) providing a material bed; and
d) providing a control system;
e) optionally providing a pressure system;
f) optionally providing a fluid drain system;
g) simultaneously introducing a curable sheath fluid and a core fluid from the hydrodynamic nozzle to form a co-flowing extrusion comprising an external sheath fluid and an internal core fluid;
h) depositing at least a portion of the co-flowing extrusion on the material bed;
I) causing relative motion between the hydrodynamic nozzle and the material bed to form an extruded shape;
j. at least partially curing a portion of the external curable fluid;
k) optionally introducing the co-flowing extrusion to pressure from the pressure system to remove the internal core fluid from the external curable fluid; and
l) optionally receiving the core fluid into the fluid drain system.

2. The method of claim 1, including the step of at least partially curing a portion of the external sheath fluid may occur before or after depositing at least a portion of the concentric extrusion on the material bed.

3. The method of claim 1, wherein the curing system is an ultraviolet (UV) curing system.

4. The method of claim 1, wherein the core fluid is a smart fluid.

5. An apparatus for forming an extruded shape comprising:
a) a hydrodynamic nozzle for creating a co-flowing extrusion formed of an external curable fluid and an internal core fluid;
b) a curing system for at least partially curing the external curable fluid;
c) a pressure system for removing the internal core fluid from the external curable fluid;
a material bed for receiving at least a portion of a co-flowing extrusion;
e) a control system for causing relative movement between the hydrodynamic nozzle and a material bed; and
f) a fluid drain system for receiving the core fluid.

6. The apparatus of claim 5, wherein the curing system is an ultraviolet (UV) curing system.

7. The apparatus of claim 5, wherein the pressure system provide positive or negative pressure.

8. The apparatus of claim 5, wherein the material bed may be capable of simultaneous linear movement in x-, y- or z-directions.

9. The apparatus of claim 5, wherein the hydrodynamic nozzle may be capable of simultaneous movement in x-, y-, z- or theta-directions.

10. The apparatus of claim 5, further comprising a ferro system that is capable of changing the position or cross-section of a shape.

11. A method for forming an extruded shape, comprising the steps of:
a) providing a hydrodynamic nozzle capable of forming an extrusion comprising an external curable fluid and an internal core fluid;
b) providing a curing system;
c. providing a material bed;
d.) providing a fluid drain system comprising at least one fluid drain;
e) providing a control system;
f) providing relative motion from the control system so that the hydrodynamic nozzle is positioned proximate to a fluid drain in the material bed;
g) forming an extrusion from the hydrodynamic nozzle so that the external curable fluid is in communication with the material bed, and the internal core fluid is in communication with the fluid drain; and
h) providing relative motion from the control system while simultaneously forming an extrusion from the hydrodynamic nozzle to form a shape having at least a hollow portion.

12. A method of forming an extruded shape, comprising:
a) providing a hydrodynamic nozzle;
b) providing a curing system;
c) providing a material bed; and
d) providing a control system;
e) providing a gravity fed system;
f) optionally providing a fluid drain system;
g) simultaneously introducing a curable sheath fluid and a core ferro fluid from the hydrodynamic nozzle to form a co-flowing extrusion comprising an external sheath fluid and an internal core fluid;
h) exposing the core fluid to a magnetic force;
i) depositing at least a portion of the co-flowing extrusion on the material bed;
j) causing relative motion between the hydrodynamic nozzle and the material bed to form an extruded shape;
k) at least partially curing a portion of the external curable fluid;
l) optionally introducing the co-flowing extrusion to pressure from the pressure system to remove the internal core fluid from the external curable fluid; and
m) optionally receiving the core fluid into the fluid drain system.

13. A method for forming an extruded shape, comprising the steps of:
a) providing a hydrodynamic nozzle capable of forming an extrusion comprising an external curable fluid and an internal core fluid containing a ferro fluid;
b) providing a curing system;
c. providing a material bed;
d.) providing a fluid drain system comprising at least one fluid drain;
e) providing a control system;
f) providing relative motion from the control system so that the hydrodynamic nozzle is positioned proximate to a fluid drain in the material bed;
g) forming an extrusion from the hydrodynamic nozzle so that the external curable fluid is in communication with the material bed, and the internal core fluid is in communication with the a magnetic force and the fluid drain; and
h) providing relative motion from the control system while simultaneously forming an extrusion from the hydrodynamic nozzle to form a shape having at least a hollow portion.

14. The method of forming an extruded shape according to claim 12, wherein said ferro core fluid is composed of a plurality of magnetic solid nano particles having a diameter of up to 10 nanometers of magnetite, hematite or compound containing iron, and a liquid to disperse them evenly within a carrier fluid.

15. The method of forming an extruded shape according to claim 14, wherein said carrier fluid is an oil.

16. The method of forming an extruded shape according to claim 14, wherein said ferro core fluid contains a surfactant.

17. The method of forming an extruded shape according to claim 14, wherein said surfactant is selected from the group consisting of an oleic acid, a tetramethylammonium hydroxide, a citric acid, a soy lecithin, and combinations thereof.

18. The method of forming an extruded shape according to claim 12, wherein said ferro core fluid contains about 5 percent magnetic solid nano particles, about 10 percent of a s surfactant, and about 85% of a carrier fluid.

19. The method of forming an extruded shape according to claim 12, wherein said ferro core fluid viscosity is from 1-10 centipoise.

20. The method of forming an extruded shape according to claim 12, wherein said ferro core carrier fluid is glycerin.
